(19) United States
(12) Patent Application Publication
(10) Pub. No.: US 2015/0201526 A1
(43) Pub. Date: Jul. 16, 2015

(54) COOLING FAN STRUCTURE OF POWER SUPPLY

(71) Applicant: CHEN-CHUNG TANG, NEW TAIPEI CITY (TW)

(72) Inventor: CHEN-CHUNG TANG, NEW TAIPEI CITY (TW)

(21) Appl. No.: 14/219,186

(22) Filed: Mar. 19, 2014

(30) Foreign Application Priority Data
Jan. 15, 2014 (TW) 103200853

(51) Int. Cl. H05K 7/20

(52) U.S. Cl. CPC H05K 7/20154

(57) ABSTRACT

A cooling fan structure of power supply includes a fan frame base face securable to a case of the power supply. The cooling fan structure is characterized in that the shaft of the cooling fan of the cooling fan structure is not perpendicular to the fan frame base face and an angle is contained between the shaft and the fan frame base face, whereby the cooling fan serves to obliquely blow cold air to the electronic components and radiating fins arranged inside the power supply. In this case, the cold air will not tarry in the power supply in which the electronic components and radiating fins are densely arranged. Accordingly, hot air can be more smoothly and quickly guided to outer side of the case of the power supply to enhance the cooling effect and effectively lower the temperature in the power supply.

### BACKGROUND OF THE INVENTION

1. Field of the Invention

The present invention relates generally to a cooling fan structure of power supply, which includes a fan frame base face securable to a case of the power supply. The cooling fan structure is characterized in that the shaft of the cooling fan of the cooling fan structure is not perpendicular to the fan frame base face and an angle is contained between the shaft and the fan frame base face, whereby the cooling fan serves to obliquely blow cold air to the electronic components and radiating fins arranged inside the power supply. In this case, hot air can be smoothly and quickly guided from the interior of the power supply to outer side of the case of the power supply to effectively lower the temperature in the power supply and enhance the cooling efficiency of the cooling fan of the power supply.

2. Description of the Prior Art

FIGS. 4 and 5 show a conventional cooling fan structure of power supply. The shaft 52 of the cooling fan 50 of the power supply 60 is normal to the base face 51 of the fan frame of the cooling fan 50. The cooling fan 50 serves to perpendicularly blow cold air A′ to the electronic components 61 and the radiating fins 62 inside the power supply 60. This will cause an eddy in the power supply 60. Under such circumstance, the cold air A′ is likely to circulate within the power supply 60. As a result, the hot air inside the power supply 60 cannot be quickly exhausted out of the case of the power supply 60. Therefore, the heat dissipation efficiency of the interior of the power supply 60 is deteriorated.

### SUMMARY OF THE INVENTION

It is therefore a primary object of the present invention to provide a cooling fan structure of power supply, which includes a fan frame base face securable to a case of the power supply. The cooling fan structure is characterized in that the shaft of the cooling fan of the cooling fan structure is not perpendicular to the fan frame base face and an angle is contained between the shaft and the fan frame base face, whereby the cooling fan serves to obliquely blow cold air to the electronic components and radiating fins arranged inside the power supply. In this case, the cold air will not tarry in the power supply in which the electronic components and radiating fins are densely arranged. Accordingly, hot air can be more smoothly and quickly guided to outer side of the case of the power supply to enhance the heat dissipation effect and effectively lower the temperature in the power supply.

In the above cooling fan structure of power supply, the shaft of the cooling fan of the cooling fan structure is not perpendicular to the fan frame base face to enhance the cooling efficiency of the cooling fan of the power supply. In addition, the cooling fan can be installed according to the configuration of the power supply 20 or the computer host case, whereby the cooling fan can obliquely blow cold air to the electronic components and the radiating fins so as to more smoothly and quickly guide the hot air to outer side of the case. Accordingly, the heat dissipation efficiency for the power supply is enhanced.

The present invention can be best understood through the following description and accompanying drawings, wherein:

### BRIEF DESCRIPTION OF THE DRAWINGS

FIG. 1 is a perspective view of the cooling fan structure of power supply of the present invention;

FIG. 2 is a sectional view taken along line 2-2 of FIG. 1;

FIG. 3 is a perspective exploded view of the cooling fan structure of power supply of the present invention;

FIG. 4 is a perspective view of a conventional cooling fan structure of power supply; and

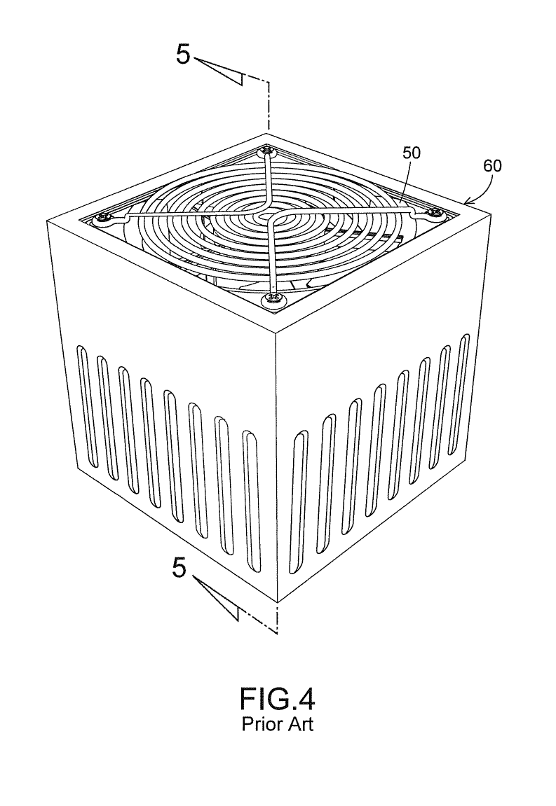

FIG. 5 is a sectional view taken along line 5-5 of FIG. 4;

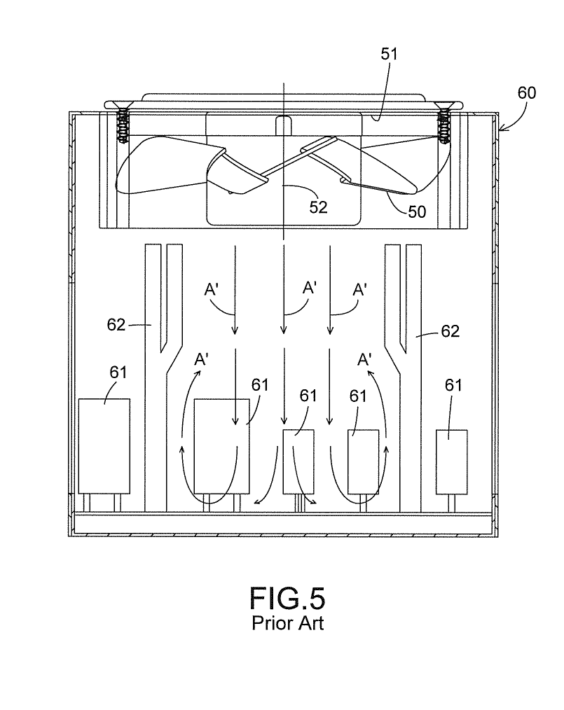

### DETAILED DESCRIPTION OF THE PREFERRED EMBODIMENTS

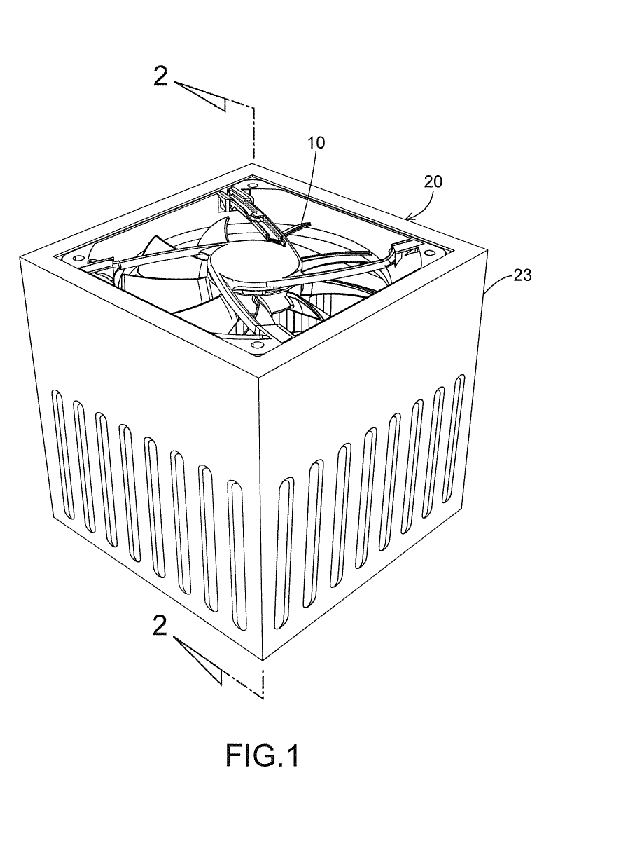

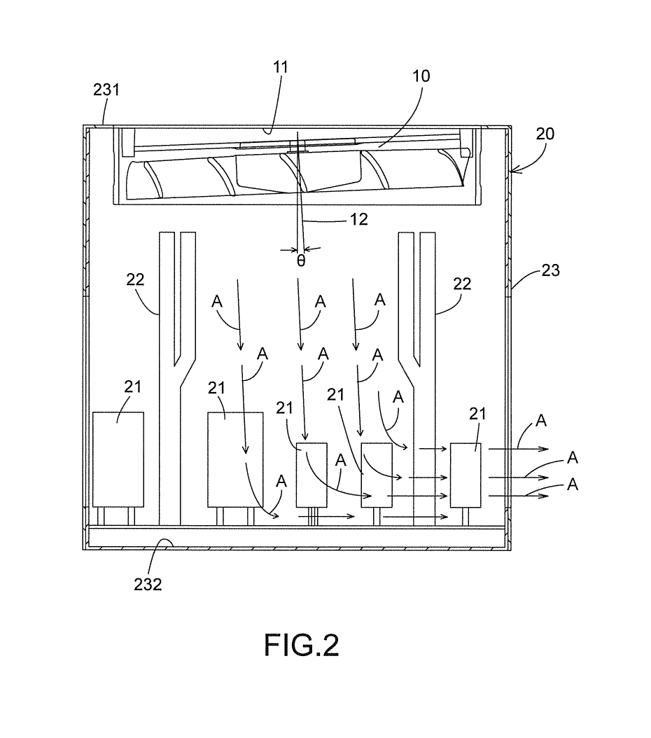

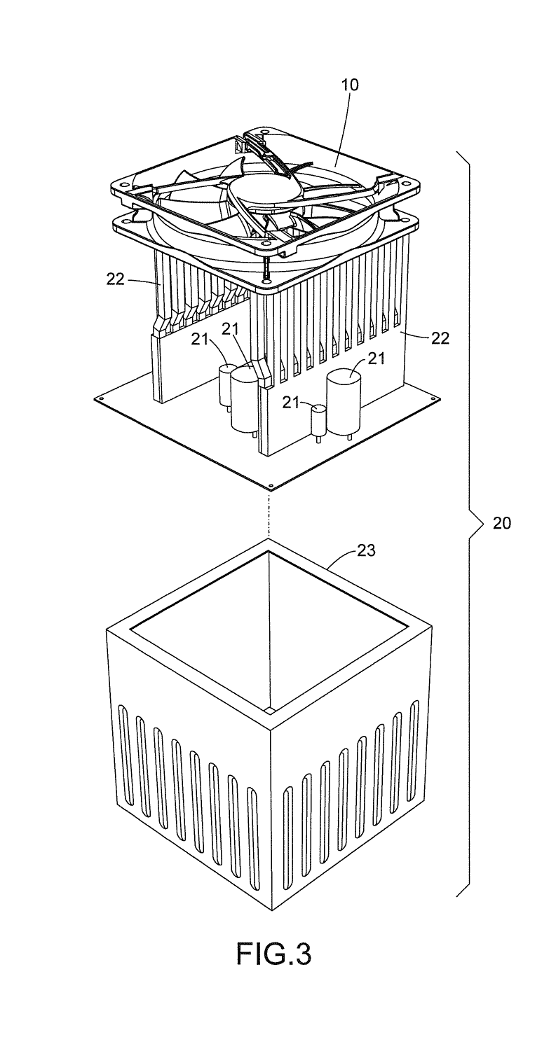

Please refer to FIGS. 1 to 3. The cooling fan structure of power supply of the present invention has a fan frame base face 11 secured to a case 23 of the power supply 20. The cooling fan structure is characterized in that the shaft 12 of the cooling fan 10 is not perpendicular to the fan frame base face 11 and an angle θ is contained between the shaft 12 and the fan frame base face 11. Accordingly, the cooling fan 10 serves to obliquely blow cold air A to the electronic components 21 and the radiating fins 22 inside the power supply 20. The case 23 has an upper face 231 for mounting the cooling fan 10 and a bottom face 232 for mounting the electronic components 21. The upper face 231 is parallel to the bottom face 232. Therefore, the cooling fan 10 also obliquely blows cold air A to the bottom face 232 of the case 23. Under such circumstance, most of the cold air A will smoothly flow out of the case 23 in one single direction without tarrying in the power supply 20 in which the electronic components 21 and the radiating fins 22 are densely arranged. Therefore, the hot air can be more smoothly and quickly guided to outer side of the case 23 to effectively lower the temperature inside the power supply 20. Accordingly, the heat dissipation effect is greatly enhanced.

Please refer to FIGS. 1 to 3. In the cooling fan structure of power supply of the present invention, the shaft 12 of the cooling fan 10 of the power supply 20 is not perpendicular to the fan frame base face 11. This can enhance the cooling efficiency of the cooling fan 10. In addition, the cooling fan 10 can be installed according to the configuration of the power supply 20 or the computer host case, whereby the cooling fan 10 can obliquely blow cold air A to the electronic components 21 and the radiating fins 22 so as to more smoothly and quickly guide the hot air to outer side of the case 23. Accordingly, the heat dissipation efficiency of the power supply 20 is enhanced.

The following is a test comparison result between a conventional cooling fan and the cooling fan of the present invention (test sample), which are mounted on the same power supply in which thermometers are respectively disposed in different positions of different components:

test comparison data between the present invention and the
conventional cooling fan (load voltages are both 230 V)

| | | temperature | |
|---|---|---|---|
| | | lowering | temperature |
| | temperature | effect of the | lowering |
| | lowering | cooling fan | effect of the |
| | effect of the | of the | present |
| | conventional | present | invention |
| component | cooling fan | invention | relative to |
| position | (° C.) (model | (° C.) ( model | the |
| (temperature | 1225, | 1218, | conventional |
| measurement | mounted in | mounted in | cooling fan |
| position) | the middle) | the middle) | (° C.) |
| BD3 bridge | 54.6 | 48.8 | −5.8 |
| rectifiers 15K | | | |
| L2 PFC | 49.1 | 36.7 | −12.4 |
| inductors | | | |
| Q03 MDF18N50 | 46.2 | 39.2 | −7 |
| Q04 MDF18N50 | 44.1 | 34.7 | −9.4 |
| BD4 PFC | 52.5 | 44.4 | −8.1 |
| rectifier tubes | | | |
| 12R06 | | | |
| Q01 MDF 18N50 | 45.6 | 40.4 | −5.2 |
| T1 master | 86.2 | 76.3 | −9.9 |
| transformer | | | |
| TM0028 | | | |
| T2 SB | 73.5 | 57.3 | −16.2 |
| transformer | | | |
| TS003 | | | |
| 12 V MOS | 77.6 | 75.6 | −2 |
| DC1 5 V inductors | 44.2 | 44.2 | −0 |
| 12 V inductors | 154.8 | 149.6 | −5.2 |

The test comparison data between the conventional cooling fan and the cooling fan of the present invention, which are mounted on the same power supply, reveal that the temperature lowering effect of the cooling fan structure of power supply of the present invention is truly better than the temperature lowering effect of the conventional cooling fan of power supply. The cooling fan structure of the present invention can smoothly and quickly guide the hot air from the interior of the power supply 20 to the outer side of the case 23 of the power supply 20. Accordingly, the temperature in the power supply 20 can be effectively and quickly lowered to greatly enhance the heat dissipation effect.

The above embodiments are only used to illustrate the present invention, not intended to limit the scope thereof. Many modifications of the above embodiments can be made without departing from the spirit of the present invention.

What is claimed is:

1. A cooling fan structure of power supply, comprising a fan frame base face securable to a case of the power supply, the cooling fan structure being characterized in that a shaft of the cooling fan of the cooling fan structure is not perpendicular to the fan frame base face, whereby the cooling fan serves to obliquely blow cold air to electronic components arranged inside the power supply so that the cold air will not tarry in the power supply in which the electronic components and radiating fins are densely arranged and hot air can be more smoothly and quickly guided to outer side of the case to effectively and quickly lower the temperature in the power supply and enhance heat dissipation effect.
